(19) United States
(12) Patent Application Publication
(10) Pub. No.: US 2005/0029572 A1
(43) Pub. Date: Feb. 10, 2005

(54) Fabrication of non-volatile memory cell

(76) Inventor: Jurriaan Schmitz, Eindhoven (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/499,395

(22) PCT Filed: Dec. 20, 2002
(86) PCT No.: PCT/IB02/05656

(30) Foreign Application Priority Data
Dec. 20, 2001 (EP) 01205040.7

(51) Int. Cl. H01L 21/336; H01L 29/76; H01L 29/788

(52) U.S. Cl. 257/314; 438/257; 438/258; 257/316

(57) ABSTRACT

Fabrication of a semiconductor device comprising a compact cellon a semiconductor substrate (3) including at least two adjacent elements separated by a spacing, the elements being defined from a layer stack that includes an isolation layer(4) on the substrate (3) and a poly-Si layer (5) on the isolation layer (4), wherein the fabrication includes:—depositing on the layer stack a mask (M1; M3) including at least one vertical isolation layer (10), a first (9) and a second (11) silicon nitride layer, the vertical isolation layer (10) separating the first (9) and second (11) silicon nitride layers and being located where the spacing is to be formed;—performing a first selective etch on the vertical isolation layer (10) to form a narrow slit (A);—performing a stack etch including a first stack etch process for selectively etching the poly-Si layer (5), using thenarrow slit (A) to define the location for the first stack etch process and the spacing between the elements.

The present invention relates to a method for the fabrication of a semiconductor device comprising a compact cell as defined in the preamble of claim 1. Furthermore, the present invention relates to a semiconductor device as defined in the preamble of claim 8.

In semiconductor device manufacturing, downscaling of non-volatile memory (NVM) cells into the 100-nm gate length regime is severely limited by the need for a low tunnel oxide leakage current. The demand for a low leakage current imposes restrictions on the thickness of tunnel oxide. In practice, this results in a lower bound thickness for tunnel oxide of approximately 6 nm.

In spite of progressing possibilities of lithographic processing, the lateral dimensions of a single NVM cell are hardly scalable due to this tunnel oxide thickness limit.

The problem is presently circumvented by the application of so-called compact cells. Such compact cells are known from U.S. Pat. No. 5,278,439 (and related U.S. Pat. No. 5,364,806 and U.S. Pat. No. 5,414,693), which describes a self-aligned dual-bit split gate (DSG) FLASH EEPROM cell. These compact cells can be characterized by the very close placement of the two transistors in a 2-T cell, significantly closer than the feature size as defined by the lithographic process.

However, the known compact cells suffer from the fact that two different gate oxides are needed, one below the floating gate and one below the control gate. Although this arrangement may be ideal for separate tuning of the oxide thickness of floating gate and control gate, the use of two (different) oxides may also introduce reliability problems.

Furthermore, the lateral isolation between poly-silicon electrodes may cause another reliability problem for these known compact cells since the dielectric quality of such isolation, normally fabricated by sidewall oxidation and sidewall spacer formation, is known to be very sensitive to technological process variations.

It is an object of the present invention to provide a method of fabricating a semiconductor device comprising compact cells in which reliability problems related to compact cells and their manufacturing are strongly reduced. Furthermore, it is an object of the present invention to provide a method for fabricating a semiconductor device comprising compact cells having lateral isolation between them of sub-lithographic size.

To achieve these and further objects, the present invention relates to a method for the fabrication of a semiconductor device comprising a compact NVM cell as defined in the preamble of claim 1, characterized in that said method comprises the following steps:
depositing, on top of the stack of layers, a first mask (M1; M3) comprising at least one vertical isolation layer (10), a first silicon nitride layer (9) and a second silicon nitride layer (11), the first mask (M1; M3) being defined by a lithographic masking process, the at least one vertical isolation layer (10) separating the first (9) and second (11) silicon nitride layers and being located above the location where the spacing between the at least two elements is to be formed;
performing a first etch to selectively remove the at least one vertical isolation layer (10) to form a narrow slit (A);
performing a stack etch comprising at least a first stack etch process for etching the at least first poly-Si layer (5) selectively to the isolation layer (4), using the narrow slit (A) to define the location for the first stack etch process and to define the spacing between the at least two elements.

Advantageously, a very compact placement of compact cells can be achieved with sub-lithographic spacing between cells. Also, in the method of manufacturing compact cells according to the present invention, oxide layers are applied between floating gate and substrate and between control gate and floating gate, the thickness of these layers being substantially equal. The dielectric quality of floating gate and control gate can thus be defined without the variations imposed by lateral sidewall formation processes such as known from the prior art.

Moreover, the present invention relates to a semiconductor device, characterized in that the spacing has a width in the range of 7-40 nm, preferably 15 nm.

Although the method of the present invention is specifically suitable for the fabrication of a 3-transistor 2-bit NVM cell and one access gate transistor, it may also be applied for (the simultaneous) fabrication of multilevel 3-transistor n-bit NVM cells and MOS devices.

Below, the invention will be explained with reference to some drawings, which are intended for illustration purposes only and do not limit the scope of protection as defined in the accompanying claims.

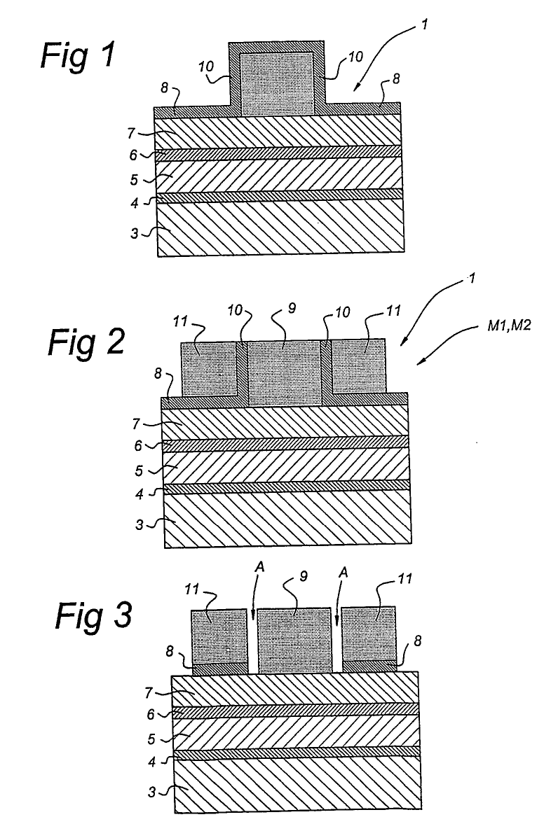

FIG. 1 shows a schematic cross-section of a first stage of a structure on a semiconductor wafer to fabricate a 3-transistor 2-bit NVM cell according to the present invention in a first preferred embodiment;

FIG. 2 shows a schematic cross-section of the structure on a semiconductor wafer to fabricate a 3-transistor 2-bit NVM cell according to the present invention after a second silicon nitride deposition step and a masking step;

FIG. 3 shows a schematic cross-section of the structure after an SiO₂ etch, selective to Si₃N₄;

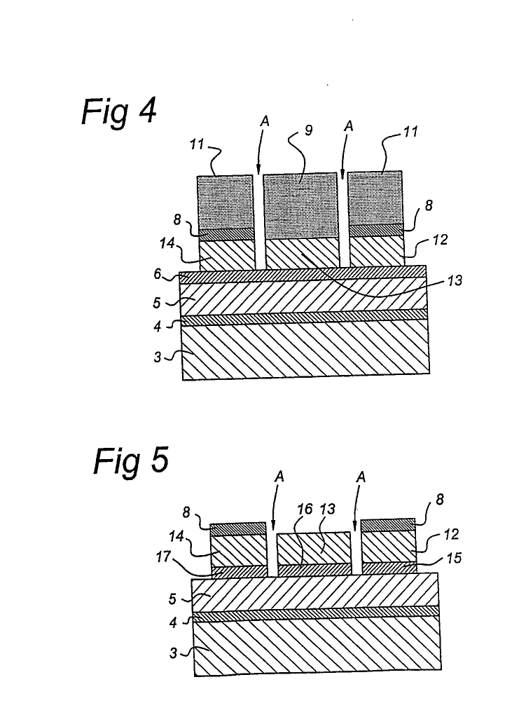

FIG. 4 shows a schematic cross-section of the structure after an Si etch, selective to Si₃N₄;

FIG. 5 shows a schematic cross-section of the structure after an SiO₂/Si₃N₄ etch, selective to Si;

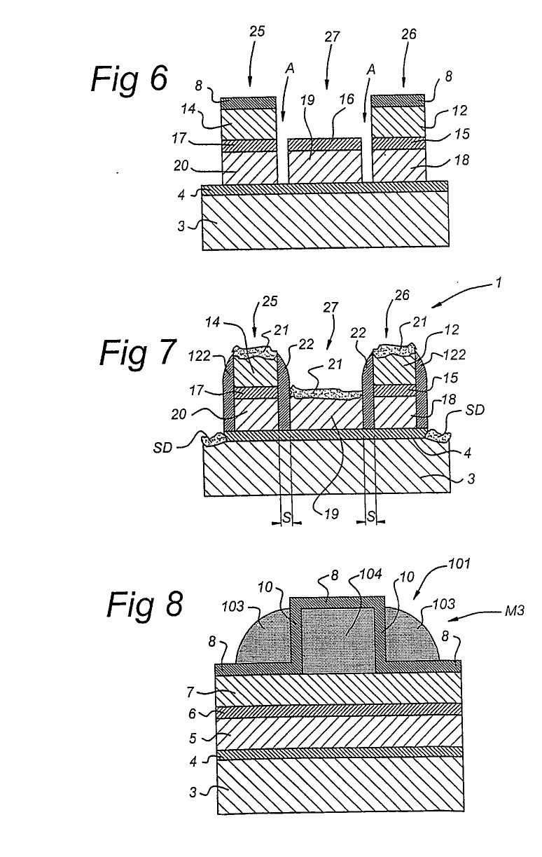

FIG. 6 shows a schematic cross-section of the structure after an Si etch, selective to SiO₂;

FIG. 7 shows a schematic cross-section of the structure after further dielectric deposition, sidewall formation and silicidation;

FIG. 8 shows a schematic cross-section of a structure on a semiconductor wafer to fabricate a 3-transistor 2-bit NVM cell according to the present invention in a second preferred embodiment;

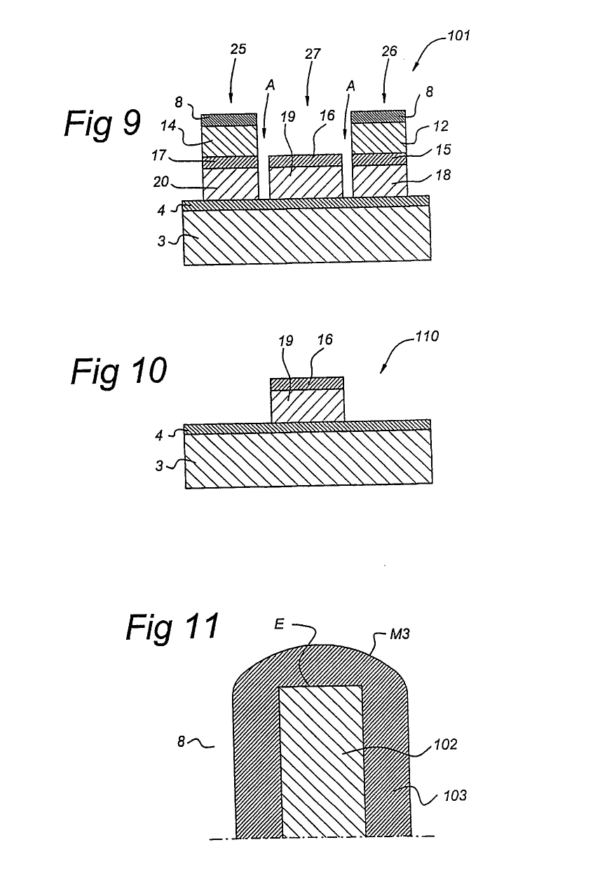

FIG. 9 shows a schematic cross-section of the structure of FIG. 8 as obtained after completion of processing steps as shown in FIGS. 3-6;

FIG. 10 shows a schematic cross-section of the structure of FIG. 8 as obtained after initial removal of the Si₃N₄ spacers followed by processing steps as shown in FIGS. 3-6;

FIG. 11 shows a top view of the schematic cross-section shown in FIG. 8.

The present invention proposes a method of fabricating an NVM cell based on standard silicon processing technology, using anisotropic etching processes to laterally isolate gates in a deep-sublithographic dimension. This approach to form lateral isolation on gates is particularly suitable for a 3-transistor cell with two floating gate/control gate stacks and one access gate transistor. The concept of such a 3-transistor cell will be described in the co-pending patent application of Widdershoven, internal reference PH-ID 605707.

FIG. 1 shows a schematic cross-section of a first stage of a structure on a semiconductor wafer to fabricate a 3-transistor 2-bit NVM cell according to the present invention in a first preferred embodiment.

The structure 1 to fabricate the 3-transistor 2-bit NVM cell according to the present invention is manufactured using standard Si processing technology as known to persons skilled in the art. In a semiconductor (Si) substrate 3, small trench isolation areas (not shown) are defined as isolation between source/drain areas to be formed. On the substrate 3, a first oxide layer 4 (SiO₂) is formed as a tunnel oxide, preferably by using a thermal oxidation process as known in the art (temperature: 600-1000° C.). Typically, the oxide layer 4 has a thickness of 6-12 nm. On top of the oxide layer 4, a first poly-Si layer 5 is deposited having a thickness in the range of 100-200 nm, possibly slightly thinner. The poly-Si layer 5 is preferably created by a chemical vapor deposition (CVD) process, using SiH₄ as a precursor and a deposition temperature of 550-650° C.

Next, on top of poly-Si layer 5, an interpoly dielectric layer 6 e.g., consisting of a multi-layer stack of “ONO” i.e., a lower silicon dioxide layer, a silicon nitride layer (Si₃N₄) and an upper silicon dioxide layer, is formed. Typically, each silicon dioxide and silicon nitride layer has a thickness of ˜6 nm. The layers are formed by processes known in the art: the lower silicon dioxide layer is formed preferably by thermal oxidation, the silicon nitride layer by a CVD Si₃N₄ process, and the upper silicon dioxide layer by a CVD SiO₂ process. Alternatively, the interpoly dielectric layer 6 may consist of an ON stack (silicon dioxide and silicon nitride) or just a single silicon dioxide layer. It will be understood that the fabrication process of the 3-transistor cell described below with reference to the application of the ONO layer as interpoly dielectric layer 6, can easily be adapted to the situation where an ON stack or just a silicon dioxide layer is applied as interpoly dielectric layer 6.

On top of the interpoly dielectric layer 6, a second poly-Si layer 7 is deposited. The second poly-Si layer 7 has a thickness, preferably, identical to the thickness of the first poly-Si layer 5, viz. 100-200 nm, or possibly thinner. The second poly-Si layer 7 is formed using a similar CVD process as that used for the first poly-Si layer 5.

Finally, a first mask construction M1 of elements consisting of a horizontal silicon dioxide layer 8, a vertical silicon dioxide layer 10 and a first silicon nitride layer 9 is formed on top of the second poly-Si layer 7. The mask construction is made as follows.

The first silicon nitride layer 9 is deposited preferably by a CVD or PECVD (plasma-enhanced CVD) process known in the art.

Next, the first silicon nitride layer 9 is patterned into a patterned first silicon nitride layer. Subsequently, a silicon dioxide deposition process (CVD or PECVD) is used to form horizontal silicon dioxide layer 8, and vertical silicon dioxide layer 10, as shown in FIG. 1.

Next, on the structure shown in FIG. 1, a second silicon nitride layer 11 is deposited. Then, a planarisation step, e.g. by using chemical-mechanical polishing (CMP), is applied to expose the first silicon nitride layer 9 in a next step.

FIG. 2 shows a schematic cross-section of the structure on a semiconductor wafer to fabricate a 3-transistor 2-bit NVM cell according to the present invention after the second silicon nitride deposition step and a masking step.

It is noted that during this stage a second mask M2 is applied to define the lateral dimensions of the silicon nitride layer 11. The mask M2 defines a pattern for the creation of outer boundaries of the exemplary 3-transistor 2-bit NVM cell in the horizontal direction shown in FIG. 2. A further demarcation may be made by mask M2 in the direction perpendicular to the plane of FIG. 2.

The width of the patterned first silicon nitride layer 9 depends on the technology level. Here it is assumed that 100 nm technology is used in the manufacturing process, and the width of the patterned first silicon nitride layer 9 is 100 nm, however, in the future these dimensions may be smaller. Accordingly, in this structure 1, the thickness of the horizontal and vertical silicon dioxide layers 8, 10 is in the range of 10-40 nm, preferably 15 nm.

As mentioned above, in the structure 1 the lateral isolation of the gates of the 3-transistor is obtained by anisotropic etching processes. The first step of the process is shown in FIG. 3.

FIG. 3 shows a schematic cross-section of the structure after an SiO₂ etch, selective to Si₃N₄. The vertical silicon dioxide layers 10 are etched in a process which is selective to silicon nitride. Thus, the selective etching process (a reactive ion etch process (RIE) or even a wet etch process, both as known from the art) removes the vertical silicon dioxide layers 10. Due to the selectivity of the etching process used, an etch stop exists at the interface with the second poly-Si layer 7. Also, the first and second silicon nitride layers 9, 11 are substantially unaffected by the etching and act as a hard mask in the formation of vertical narrow slits, indicated by arrows “A”, at the location of the (former) vertical silicon dioxide layers 10. The vertical narrow slits have substantially the same width as the vertical silicon dioxide layers 10, viz. 10-40 nm, preferably, 15 nM.

FIG. 4 shows a schematic cross-section of the structure after an Si etch, selective to Si₃N₄. The Si etching process is an anisotropic etching process, which uses the hard mask formed by the first and second silicon nitride layers 9, 11 to extend the narrow slits A to the interface of the second poly-Si layer 7 and the interpoly dielectric layer 6. The interpoly dielectric layer 6 acts as etch stop, since the etching process is selective to silicon nitride. Separate second level poly-Si blocks 12, 13, 14 are formed by the etching process.

FIG. 5 shows a schematic cross-section of the structure after an SiO₂/Si₃N₄ etch, selective to Si. In the step shown in FIG. 5, the first and second silicon nitride layers 9, 11 are removed as well as parts of the interpoly dielectric layer 6 that are located in the narrow slits A. Thus, separate interpoly dielectric layer parts 15, 16, 17 are formed.

It is noted that during this step the etch rate and etching time of the process must be checked carefully in order to preserve the horizontal silicon dioxide layers 8, which are now the top level of the structure. If case the ONO layer is used as interpoly dielectric layer 6, the etching process is a three step process. The first etch step uses a RIE process to etch the upper silicon dioxide layer of the ONO stack. The next step uses a RIE process to etch the silicon nitride layer of the ONO stack. The third step may be either a RIE process or a wet etch process to etch the lower silicon dioxide layer of the ONO stack.

It is noted that, advantageously, a wet etch process also removes a part of the silicon dioxide layer of the ONO stack in the horizontal direction (creating an undercut, not shown, with respect to the first and second poly-Si layers 5, 7). At a later stage when an oxidation step is applied to the walls of the narrow slits, the edges of first and second poly-Si layers 5, 7 extending into the narrow slit become rounded which will reduce the probability of electrical discharge at the edges.

After this step, the narrow slits A are to be extended further into the first poly-Si layer 5.

FIG. 6 shows a schematic cross-section of the structure after an Si etch, selective to SiO₂. In the step preceding the state shown in FIG. 6, an RIE process for anisotropic etching of Si is carried out to complete the formation of the narrow slits A and separate first level poly-Si blocks 18, 19, 20. Concurrently, the separate second level poly-Si block 13 is removed in this step. The tunnel oxide layer 4 acts as etch stop for this process, since the applied RIME process is selective to SiO₂. RIE processes of this type are well known to persons skilled in the art.

The structure now encompasses a first floating gate/control gate stack 25, a second floating gate/control gate stack 26 and an access gate stack 27.

In further processing steps, re-oxidation and/or dielectric deposition may be used to fill the narrow slits A so as to obtain lateral isolation blocks 22. Furthermore, formation of spacers 122 around the structure results in the creation of open Si areas on source and drain areas SD, control gates 12, 14, and access gate 19. In a subsequent step, self-aligned silicidation of these areas can be carried out simultaneously, yielding silicided areas 21 on top of the respective areas 12, 14, 19, SD.

FIG. 7 shows a schematic cross-section of the structure after further dielectric deposition, sidewall formation and silicidation.

Further processing such as e.g., metallization and passivation steps can be done by any suitable fabrication process known in the art.

Advantageously, the method of the present invention allows the spacing S between device elements such as floating gate/control gate stack 25, 26 and access gate 27 to be much smaller than the feature size imposed by lithography. Here, the spacing S is substantially equal to the thickness of lateral isolation blocks 22, i.e., the thickness of (former) vertical silicon dioxide layer 10. The close spacing allows for further densification of devices, in this case 3-transistor 2-bit NVM cells, which can not be achieved by the lithographic processing known from the prior art. It is noted that only two masks M1, M2 are needed to define the structure shown in FIG. 6 and FIG. 7.

Below, a second preferred embodiment according to the present invention will be described in more detail. In FIGS. 8-10 entities with the same reference number refer to the same entities as shown in FIGS. 1-7.

FIG. 8 shows a schematic cross-section of a structure 101 on a semiconductor wafer to fabricate a 3-transistor 2-bit NVM cell according to the present invention in a second preferred embodiment.

Instead of the first mask construction M1 comprising the horizontal silicon dioxide layer 8, the vertical silicon dioxide layer 10 and the first and second silicon nitride layers 9, 11 as shown in FIG. 2, an alternative mask construction M3 is used as hard mask to define the narrow slits A. The alternative mask construction M3 consists of the horizontal silicon dioxide layer 8, the vertical silicon dioxide layer 10, a second horizontal silicon dioxide layer 102, a first silicon nitride block 104 and silicon nitride sidewall spacers 103.

Alternative mask construction M3 is made in the following way.

A first silicon nitride layer is deposited preferably by a CVD or PECVD plasma-enhanced CVD) process known in the art.

Next, the silicon nitride layer is patterned into first silicon nitride block 104, which is line shaped in the direction orthogonal to the shown cross-section.

Subsequently, a silicon dioxide deposition process (CVD or PECVD) is used to form the horizontal silicon dioxide layer 8, the vertical silicon dioxide layer 10 and the second horizontal silicon dioxide layer 102.

Then, the silicon nitride sidewall spacers 103 are formed. Advantageously, in this embodiment, the entire structure 101 is self-aligned to the lithographic step (defining the first silicon nitride block 104). In the spacer formation process, the width of the silicon nitride sidewall spacers 103 requires attention, since this width will define the lateral size of the floating gate/control gate stacks 25, 26.

Furthermore, when the alternative mask construction M3 is used, no planarisation step is needed.

FIG. 11 shows a top view of the schematic cross-section shown in FIG. 8. The stack extends in one direction to form a line-shaped stack. In FIG. 11, the end-part of the line-shaped stack is depicted by the isolation layer 8, 102 and silicon nitride sidewall spacers 103. As shown in FIG. 11, at the longitudinal end E of the line-shaped stack the sidewall spacers extend around the stack, so that the first and second floating gate/control gate stacks 25, 26 to be formed are interconnected, which is disadvantageous. An additional masking step and etching process M4 will be required to remove the silicon nitride sidewall spacers at these ends in order to break the connection during further processing of the stack. This additional masking and etching process M4 can be done at a very early stage, right after the definition of the alternative mask construction M3.

Furthermore, it is noted that it is a prerequisite here that the stack etch defining the narrow slits A can be used at the same time to etch the outer sides of the floating gate/control gate stacks.

FIG. 9 shows a schematic cross-section of the structure 101 of FIG. 8 as obtained after completion of processing steps, while using the silicon nitride sidewall spacers 103 as a mask. Here, a 3-transistor 2-bit NVM cell is obtained which is similar to the structure 1 shown in FIG. 6.

FIG. 10 shows a schematic cross-section of a MOS structure of FIG. 8, as can be obtained after initial removal of the Si₃N₄ sidewall spacers in the structure of FIG. 8 followed by processing steps as shown in FIGS. 3-6.

Initial removal of the silicon nitride sidewall spacers 103 results in a simple transistor 110. It is noted that by using the alternative mask constructions M3 (and M4) with and without the step of removing silicon nitride sidewall spacers 103, the same fabrication steps can be used for the gate definition of MOS devices and NVM cells, thereby saving processing steps.

Just as in the first preferred embodiment, re-oxidation and/or dielectric deposition, formation of spacers, silicidation and further processing such as e.g., metallization and passivation steps can be carried out as described above.

Although in the preceding examples a 3-transistor 2-bit non-volatile memory cell is described, it is noted that the fabrication process according to the present invention is not restricted to such non-volatile memory cells, but may also be used for example for multilevel 3-transistor n-bit non-volatile memory cells, or other devices with small internal spacings.

1. Method for fabricating a semiconductor device comprising a compact cell on a semiconductor substrate (3) comprising at least two adjacent elements with a spacing between them, said at least two elements being defined from a stack of layers, said stack of layers comprising at least an isolation layer (4) on said substrate (3) and at least a first poly-Si layer (5) on said isolation layer (4), characterized in that said method comprises the following steps:
depositing, on top of said stack of layers, a first mask (M1; M3) comprising at least one vertical isolation layer (10), a first silicon nitride layer (9) and a second silicon nitride layer (11), said first mask (M1; M3) being defined by a lithographic masking process, said at least one vertical isolation layer (10) separating said first (9) and second (11) silicon nitride layers and being located above the location where said spacing between said at least two elements is to be formed;
performing a first etch to selectively remove said at least one vertical isolation layer (10) to form a narrow slit (A);
performing a stack etch comprising at least a first stack etch process for etching said at least first poly-Si layer (5) selectively to said isolation layer (4), using said narrow slit (A) to define the location for said first stack etch process and to define the spacing between said at least two elements.

2. Method for fabricating a semiconductor device comprising a compact cell according to claim 1, characterized in that said method comprises the following steps:
demarcating in said second silicon nitride layer (11) the outer boundaries of each of said at least two elements by a second mask (M2; M4);
to remove said second silicon nitride layer (11) at said outer boundaries by a further etching process.

3. Method for fabricating a semiconductor device comprising a compact cell according to claim 1, characterized in that
said stack of layers comprises an interpoly dielectric layer (6) on top of said first poly-Si layer (5) and a second poly-Si layer (7) on top of said interpoly dielectric layer (6); and
said stack etch comprises a second stack etch process for etching said second poly-Si layer (7) selectively to said interpoly dielectric layer (6), using said narrow slit (A) to define the location for said second stack etch process;
said stack etch comprises a third stack etch process for etching said interpoly dielectric layer (6) selectively to said first poly-Si layer (5), using said narrow slit (A) to define the location for said third stack etch process.

4. Method for fabricating a semiconductor device comprising a compact cell according to claim 1, characterized in that said compact cell is a non-volatile memory cell (1; 101), said at least two elements comprising a first floating gate/control gate stack (25), a second floating gate/control gate stack (26) and an access gate stack (27), said access gate (27) being located in between said first and second floating gate/control gate stacks (25, 26), said narrow slit (A) being located in between said first floating gate/control gate stack (25) and said access gate stack (27) and said narrow slit (A) being located in between said second floating gate/control gate stack (26) and said access gate stack (27).

5. Method for fabricating a semiconductor device comprising a compact cell according to claim 1, characterized in that said second silicon nitride layer (11) of said first mask (M3) comprises silicon nitride sidewall spacers (103).

6. Method for fabricating a semiconductor device comprising a plurality of compact cells on a semiconductor substrate (3), using the method as defined in claim 3.

7. Method for fabricating a semiconductor device comprising a plurality of compact cells on a semiconductor substrate (3), using the method as defined in claim 5 to fabricate at least one transistor element (110) by removing said silicon nitride sidewall spacers (103) at at least one predetermined location in said first mask (M1; M3) prior to said stack etch.

8. Semiconductor device having a semiconductor substrate (3) comprising at least two adjacent elements adjacent with a spacing between them, said at least two elements being defined from a stack of layers comprising at least an isolation layer (4) on said substrate (3) and at least a first poly-Si layer (5) on said isolation layer (4), said at least two elements being, at least partly, defined in said first poly-Si layer (5), characterized in that said spacing has a width in the range of 7-40 nm, preferably 15 nm.

9. Semiconductor device according to claim 8, characterized in that the at least two elements are part of a multilevel 3-transistor n-bit non-volatile memory cell.

10. Semiconductor device according to claim 9, characterized in that said multilevel 3-transistor n-bit non-volatile memory cell is a 3-transistor 2-bit non-volatile memory cell.

11. Semiconductor device according to claim 8, characterized in that the semiconductor device comprises a plurality of 3-transistor n-bit non-volatile memory cells.

12. Semiconductor device according to any of the claim 8, characterized in that the semiconductor device also comprises at least one transistor element (110).

13. Semiconductor device according to claim 12, characterized in that the at least one transistor element comprises a MOS device (110).
